(19) United States
(12) Patent Application Publication
(10) Pub. No.: US 2010/0051445 A1
(43) Pub. Date: Mar. 4, 2010

(54) Coating Apparatus For The Coating Of A Substrate, As Well As A Method For The Coating Of A Substrate

(76) Inventors: Jörg Vetter, Bergisch Gladbach (DE); Georg Erkens, Aachen (DE)

Correspondence Address: ROBERT S. GREEN, SULZER METCO (US), INC., 1101 PROSPECT AVENUE, WESTBURY, NY, 11590, US

(21) Appl. No.: 12/550,600

(22) Filed: Aug. 31, 2009

(30) Foreign Application Priority Data
Sep. 2, 2008 (EP) 08163508.8

(51) Int. Cl. C23C 14/35

(52) U.S. Cl. 204/192.12; 204/298.06

(57) ABSTRACT

The present invention relates to a vaporization apparatus (1) for the vaporization of a target material (200, 201, 202). The vaporization apparatus (1) includes a process chamber (3) for the setting up and maintenance of a gas atmosphere and having an inlet (4) and an outlet (5) for a process gas, as well as an anode (6, 61) and a cylindrical vaporization cathode (2, 21, 22) formed as a target (2, 21, 22), the cylindrical vaporization cathode (2, 21, 22) including the target material (200, 201, 202). Furthermore, an electrical source of energy (7, 71, 72) is provided for the generation of an electric potential between the anode (6, 61) and the cathode (2, 21, 22) so that the target material (200, 201, 202) of the cylindrical cathode (2, 21, 22) can be transferred into a vapor phase by means of the electrical source of energy (7, 71, 72), with a magnetic field source (8, 81, 82) generating a magnetic field being provided. In accordance with the invention a cylindrical vaporization cathode (2, 21) and a cylindrical arc cathode (2, 22) are simultaneously provided in the process chamber (3). Furthermore, the invention relates to a coating method for the coating of a substrate (S).

The invention relates to a vaporization apparatus for the vaporization of a target material, as well as to a method for the coating of a substrate in accordance with the preamble of the independent claim of the respective category.

A whole series of different chemical, mechanical and physical procedures for the application of layers or layer systems onto a very diverse range of substrates is known in the prior art which, depending on their requirement and their field of application, are valid and have corresponding advantages and disadvantages.

For the application of comparatively thin layers methods are particularly commonly known in which the surface of a target is transferred into the vapor state in an arc or atoms are transferred into the vapor state from a surface of a target by means of ionized particles, with the thus formed vapor then being able to be deposited as a coating on a substrate.

In a typical embodiment of cathode atomization in a sputtering process the target is connected to a negative direct current voltage source or to a high ratio frequency current source. The substrate is the material to be coated and it is provided, for example, opposite the target. The substrate can be subjected to grounding, floating, biasing, heating, cooling or a combination thereof. A process gas is introduced into the process chamber containing, among other things the process electrodes and the substrate, to achieve a gas atmosphere, in which a corona discharge can be triggered and maintained. Depending on the application, the gas pressures range from a few tenths of a Pascal up to a plurality of Pascals. A commonly used atomizing gas is argon.

On triggering the corona discharge, positive ions are incident on the surface of the target and primarily release neutral target atoms by the transfer of momentum and these then condense on the substrate to form thin films. In addition, there are other particles and radiations which are generated by the target and they all have film forming properties (secondary electrons and secondary ions, desorbed gases and photons). The electrons and negatively charged ions are accelerated toward the substrate platform and bombard it and the growing film. In some cases, for example, a negative bias voltage is applied to the substrate holder so that the growing film is subjected to the bombardment of positive ions. This process is also known as bias sputtering or ion plating.

In certain cases no argon gases are used, but rather other gases or gas mixtures. This normally includes a few types of reaction sputtering processes in which a composition is synthesized by the coating of a metal target (e.g. Ti) in an at least partially reactive reaction gas to form a composition of the metal and the reaction gas types (e.g. titanium oxide). The atomization yield is defined as the number of atoms ejected from the target surface per incident ion. It is an essential parameter for the characterization of the atomization process.

Approximately one percent of the energy incident on the surface of the target generally leads to the expulsion of vaporized particles, 75% of the incident energy leads to a heating of the target and the remainder is, for example, scattered by secondary electrons which can bombard and heat the substrate. An improved process known as magnetron sputtering uses magnetic fields to guide the electrons away from the substrate surface, whereby the influence of heat is reduced.

For a given target material the rate of application and the uniformity are among other things influenced by the system geometry, the target voltage, the sputtering gas, the gas pressure and the electric power applied to the process electrodes.

A related physical coating method is the known as arc vaporization in its versatile embodiments.

On arc sputtering the target material is vaporized by the effect of vacuum arcs. The target source material is the cathode in the arc circuit. The fundamental components of a known arc vaporization system include a vacuum chamber, a cathode and an arc current connection, parts for the ignition of an arc on the cathode surface, an anode, a substrate and a current source for a substrate bias. The arcs are maintained by voltages in the range of, for example, 15-50 volts depending on the target cathode material used. Typical arc currents are in the range of 30-400 A. The arc ignition is achieved by typical ignition methods known to the person of ordinary skill in the art.

The vaporization of the target material from the cathode, forming the target, is achieved as the result of a cathode arc point which in the simplest case moves randomly on the cathode surface at speeds of typically 10 m/s. However, the arc point movement can also be controlled with the aid of suitable inclusion boundaries and/or magnetic fields. The target cathode material can be a metal or a metal alloy, for example.

The arc coating process is significantly different to other physical vapor coating processes. The core of the known arc processes is the arc point which generates a plasma medium. A high percentage, for example, 30%-100% of the material evaporated from the cathode surface is normally ionized, with the ions being able to exist in different charge states in the plasma, for example, as Ti+, Ti2+, Ti3+, etc. The kinetic energy of the ions can vary in the range of e.g. 10-100 e.V.

These features lead to coatings, which can be of the highest quality and can have certain advantages compared to those coatings which are applied using other physical vapor coating processes.

The coatings applied by means of arc vaporization usually show a high quality for a large range of the coating properties. For example, stoichiometric compound films with the highest adhesion and high density can be produced having high coating yields for metals, alloys and compositions with excellent coating uniformity over a wide range of the reaction gas pressure. Beside other advantages, a further advantage is also the relatively low substrate temperatures and the relatively simple production of compound films.

The cathode arc leads to a plasma discharge within the material vapor released from the cathode surface. The arc point is normally a few micrometers large and has current densities of 10 amperes per square micrometer. This high current density causes an instantaneous vaporization of the raw material and the generated vapor includes electrons, ions, neutral vapor atoms and micro drops. The electrons are accelerated toward the clouds of positive ions. The emissions of the cathode light point are relatively constant for a wide range of the arc current if the cathode point is divided into a plurality of points. The average current per point depends on the nature of the cathode material.

Often almost 100% of the material within the cathode point region is ionized. These ions are ejected in a direction almost perpendicular to the cathode surface. Furthermore, micro drops are generated as a rule which are forced to exit the cathode area at angles of, for example, up to 30% above the cathode plane. These micro drop emissions are a result of extreme temperatures and forces present within the emission crater.

Thus, even today, the cathode arc plasma coating process is still seen as unsuitable for decorative applications, and indeed due to the micro drops in the film.

The latest developments, including the elimination of micro drops in the arc coating process, have developed an important alternative to the existing procedures for a wide range of applications and also, but not exclusively, for decorative applications.

The known arc processes are also, in this respect, characterized by a high flexibility. Thus, for example the control of the coating parameters is less critical than for magnetron vaporization processes or ion plating processes.

The coating temperature can be set to significantly lower temperatures for compound films so that the possibility is given to completely coat substrates, such as, cast zinc, brass and plastics, without melting the substrate.

In conclusion, under certain circumstances the known arc coating processes offer a series of advantages with respect to the above mentioned atomization processes, by means of sputtering.

Nevertheless, a number of coatings in particular for, but not only for, decorative applications and/or applications in microelectronics, in the field of optics or other applications which require a thin film, are preferably carried out using an atomization process. Preferred materials for the sputtering are, for example, sulfides (e.g. MoS₂) or also brittle materials (e.g. TiB₂). Ultimately, in principle all materials which are in anyway arc-compatible.

Among other things, this depends on the problems of eliminating the mentioned micro drops. For this reason vaporization is still the preferred method today, for example, to apply a thin gold coat for decorative purposes or thin layers in electronics or optics. However, frequently the layers applied by the sputtering processes have other undesired properties, for example, in relation to ageing, hardness, adhesion or they have deficiencies regarding the resistance to different outer influences and can thus be influenced or even removed.

Depending on the application it can thus be advantageous to provide a combination of layers on a substrate, with one of the layers being a layer applied, for example, by sputtering and a different layer being a layer applied using an arc process.

In WO 90/02216 a coating apparatus is disclosed for the production of decorative gold coatings which simultaneously includes a conventional rectangular sputtering source and a rectangular cathode arc vaporization source. In accordance with the method likewise disclosed in this document, in a first method step a layer of TiN is applied using a cathode arc method with, in a subsequent step, a gold layer being sputtered on so that the layer system collectively essentially has the same appearance as a simple coating of gold on its own.

Among others, a disadvantage of the coating apparatus and of the method in accordance with WO 90/02216 consists in that in particular a uniform quality of the coatings is not guaranteed. For example, with increasing use of the cathode the quality of the applied layers changes, unless the process parameters are correspondingly altered in a complex and/or expensive process. Among other things, this is due, as is known, to the fact that the rectangular cathodes wear non-uniformly, so that with the same method parameters the quality of the coating vapor continuously deteriorates with an increased erosion of the cathode, because, for example, in increased measures, interfering drops are generated during the arc vaporization which negatively influences the layers. To contain these negative effects the cathodes have to be replaced prematurely, which is correspondingly expensive and complex.

A further disadvantage beside the non-uniform erosion of the cathodes is that a control of the arc on the cathode is extremely complex and expensive if at all possible.

A cathode for sputtering and a second separate cathode for arc vaporization must also necessarily be provided, because not even when a round or rectangular combined cathode is used which is provided with different materials in two different regions, for example, can one and the same cathode be used for the sputtering and the arc coating.

It is therefore the object of the present invention to provide an improved coating apparatus and to suggest a method for coating with which a substrate can be coated in one and the same coating chamber largely defect free both by arc vaporization and also by means of a sputtering process; in particular, but not necessarily also with different materials, so that in particular combination layer systems can be produced easily and cost effectively which satisfy the highest demands on quality.

The subjects of the invention satisfying these objects with regard to the apparatus and the process engineering aspects are characterized by the features of the independent claims of the respective category.

The dependent claims relate to particularly advantageous embodiments of the invention.

The invention thus relates to a vaporization apparatus for the vaporization of a target material. The vaporization apparatus includes a process chamber for the setting up and maintenance of a gas atmosphere and has an inlet and an outlet for a process gas, as well as an anode and a cylindrical vaporization cathode formed as a cathode, with the cylindrical vaporization cathode including the target material. Furthermore, an electrical source of energy is provided for the generation of an electric potential between the anode and the cathode so that the target material of the cylindrical cathode can be transferred into a vapor phase by means of the electrical source of energy, with a magnetic field source generating a magnetic field being provided. In accordance with the invention a cylindrical vaporization cathode and a cylindrical arc cathode are simultaneously provided in the process chamber.

It is thus possible using the invention to provide a combination of layers on a substrate with one of the layers being, for example, a layer applied by sputtering and another layer being a layer applied by arc processes.

In this respect the disadvantages known from the prior art such as, for example, exist in the coating apparatus and the method in accordance with WO 90/02216 are avoided by the invention. Utilizing the present invention it is possible for the first time to guarantee in particular a uniform quality of the coatings. For example, the quality of the applied layers does not change with an increased wear of the cathodes and the process parameters do not have to be adapted in a complex and/or expensive manner. Among other things this is due to the fact that the cathodes in accordance with the invention wear uniformly so that with constant process parameters the quality of the coating vapor remains the same and therefore does not deteriorate on an increased erosion of the cathode, for example, because interfering drops are generated to an increased degree in arc vaporization which negatively influences the layers. Since these negative influences practically no longer occur in the present invention, the cathodes do not have to be prematurely replaced as in the prior art, which leads to correspondingly considerable cost reductions.

Due to the cylindrical shape of the cathodes and the flexibility of the arrangement of the magnetic field sources, the control of the arc on the cathode is also particularly simple and flexible.

One cathode for the vaporization and a second separate cathode be provided for the arc vaporization also no longer have to be provided as compulsory, because with a suitable adaptation of the vaporization cathode, one and the same vaporization cathode can be used for sputtering and for arc coating.

An improved coating apparatus and an improved method for coating are thus suggested by the invention, with which a substrate can be coated largely defect free in one and the same coating chamber both by arc vaporization and also by means of a sputtering process, in particular but not necessarily also with different materials so that in particular combination layer systems can be produced simply and cost effectively which satisfy the highest demands on quality.

The coating apparatus in accordance with invention and the method in accordance with the invention can be used in a very universal and flexible manner. Among other things, for instance, such diverse objects such as tools, heavily used machine components, decorative surfaces can be coated. But also in the field of optics, micromechanics, microelectronics, e.g. in medical technology, and/or for the coating of elements of nanosensors or for nanoengines the invention can be used particularly advantageously.

In a specific embodiment the cylindrical vaporization cathode and/or the cylindrical arc cathode is adapted for rotation about a longitudinal axis.

The magnetic field source is preferably provided in an interior of the cylindrical vaporization cathode and/or in an interior of the cylindrical arc cathode, and/or the cylindrical vaporization cathode and/or the cylindrical arc cathode is/are arranged rotatably relative to the magnetic field source.

The magnetic field source is advantageously a permanent magnet and/or an electromagnet, with a position of the magnetic field source being able to be set in the interior of the cylindrical vaporization cathode and/or in the interior of the cylindrical arc cathode, in particular in relation to an axial position and/or to a radial position and/or in relation to a peripheral direction.

It shall be understood that in particular a strength of the magnetic field of the magnetic field source is controllable and/or regulatable, with the magnetic field source preferably being provided and arranged in such a way that a magnetic field strength of the magnetic field is changeable in a presettable region of the cylindrical vaporization cathode.

A possibility for the vaporization cathode is a balanced magnetron and/or an imbalanced magnetron, for example.

Advantageously one and the same vaporization cathode can be adapted and arranged in the process chamber such that the vaporization cathode can be used both as a vaporization cathode and also as an arc cathode.

Furthermore, the invention relates to a method for the coating of a substrate in a process chamber, in which process chamber a gas atmosphere is set up and maintained. An anode and a cylindrical vaporization cathode formed as a target are provided in the process chamber, which cylindrical vaporization cathode includes the target material. The target material of the cylindrical cathode can be transferred into a vapor phase by means of an electrical source of energy, with a magnetic field source generating a magnetic field being provided in the process chamber such that a magnetic field strength of the magnetic field can be changed in a preset region of the cylindrical vaporization cathode. In accordance with the invention a cylindrical vaporization cathode and a cylindrical arc cathode are simultaneously provided in the process chamber and the substrate is coated using an arc vaporization process and/or with a cathode vaporization process.

Preferably the cylindrical vaporization cathode is rotated about a longitudinal axis during a coating process for a uniform utilization of the target material.

In a special embodiment a position of the magnetic field source, can in this respect be set in an interior of the cylindrical vaporization cathode and/or in an interior of the cylindrical arc cathode, in particular in relation to an axial position and/or to a radial position and/or in relation to a peripheral direction, with a strength of the magnetic field of the magnetic field source being controlled and/or regulated.

In particular one and the same vaporization cathode is used as the vaporization cathode and as the arc cathode.

Advantageously a balanced magnetron and/or an imbalanced magnetron can be used as the sputtering cathode.

The coating process can in this respect be a DC sputtering process and/or an RF sputtering process and/or a pulsed sputtering process and/or a high power sputtering process and/or a DC arc vaporization process and/or a pulsed arc vaporization process and/or a different coating process which can be carried out using the vaporization apparatus in accordance with the invention.

The invention will be described in more detail in the following with reference to the schematic drawing. There is shown:

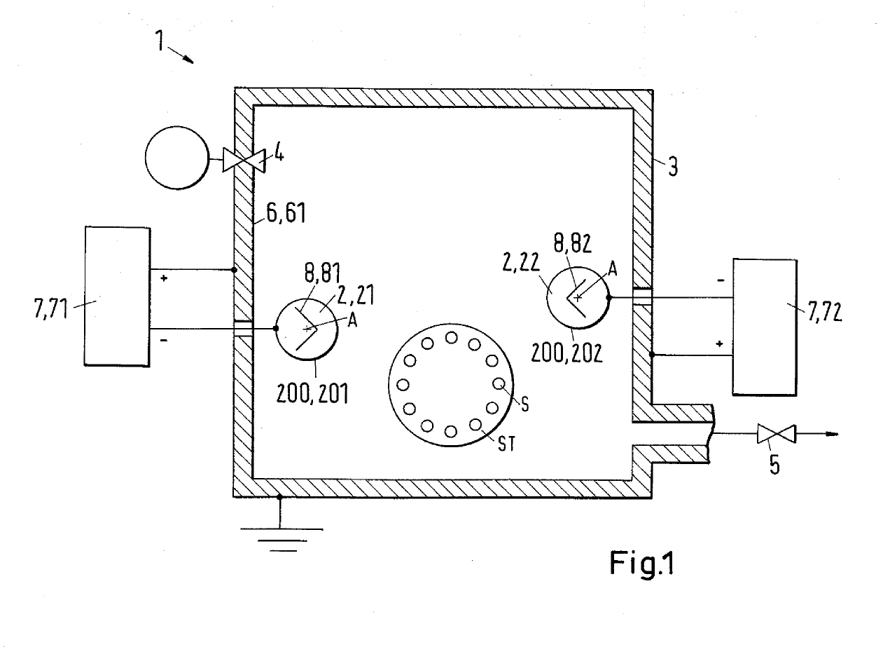

FIG. 1 a simple embodiment of a vaporization apparatus in accordance with the invention;

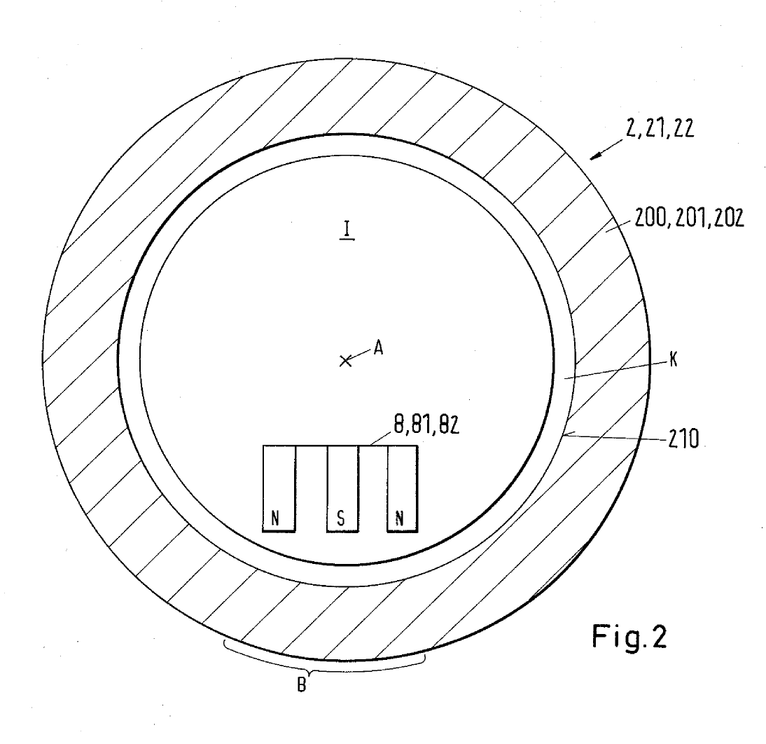

FIG. 2 a first embodiment of a vaporization cathode with a permanent magnetic field source;

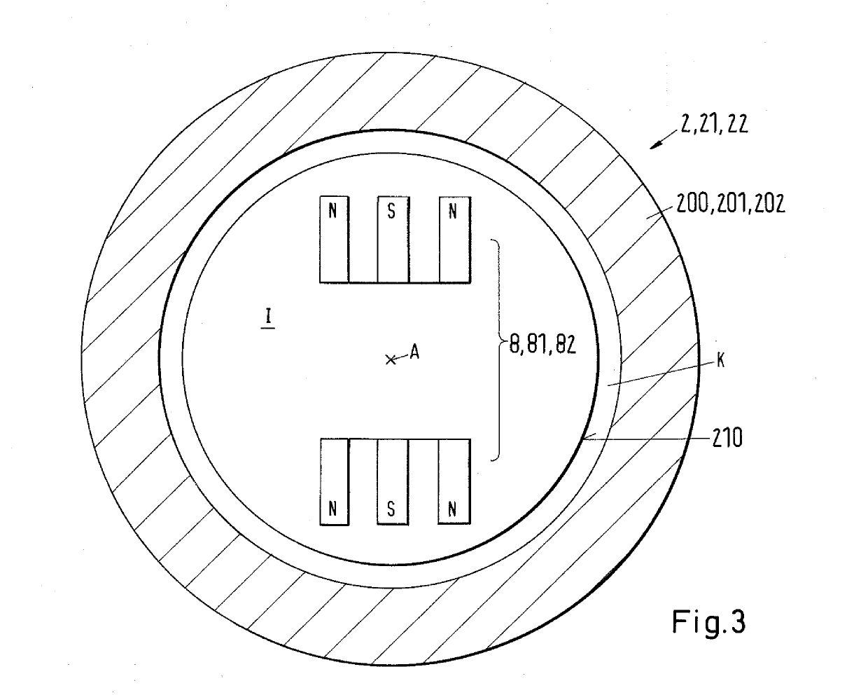

FIG. 3 a second embodiment in accordance with FIG. 2;

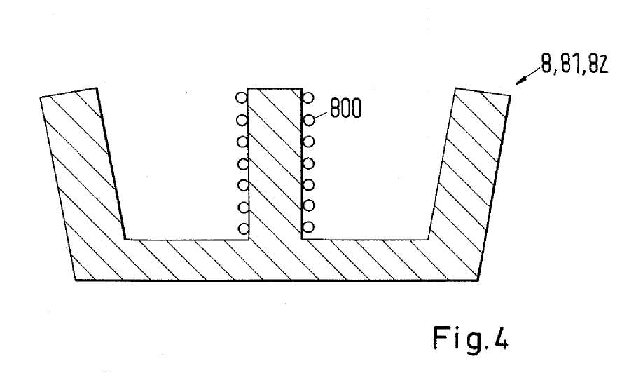

FIG. 4 a magnetic field source with a central coil winding;

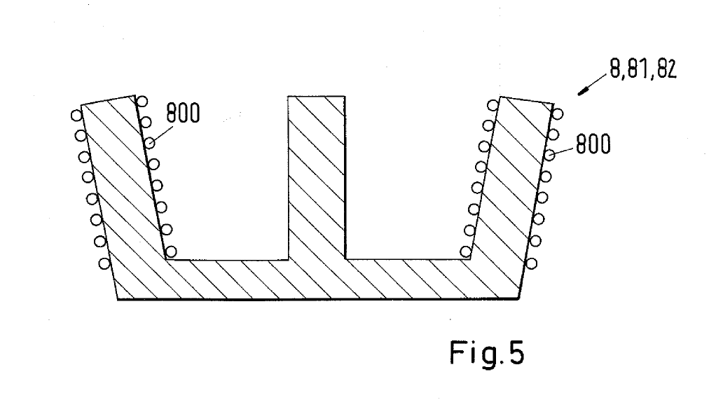

FIG. 5 a magnetic field source with two separate coil windings;

In a schematic illustration, FIG. 1 shows a simple embodiment of a vaporization apparatus 1 in accordance with the invention for the vaporization of a target material 200, 201, 202. The vaporization apparatus 1 includes a process chamber 3 for the setting up and maintenance of a gas atmosphere, the process chamber 3 having an inlet 4 and an outlet 5 for a process gas. An anode 6, 61 for the cylindrical vaporization cathode 2, 21 is provided in the process chamber 3, with in the present example of FIG. 1 the anode 61 associated with the vaporization cathode 21 being formed by the chamber wall of the process chamber. The anode 61 and the vaporization cathode 21 are connected to an electrical source of energy 7, 71 for the supply of electrical energy.

Both cylindrical vaporization cathodes 2, 21, 22 respectively include a magnetic field source 8, 81, 82 generating a magnetic field which is provided such that a magnetic field strength of the magnetic field is changeable in a predeterminable region of the cylindrical vaporization cathode 2, 21, 22. This is achieved in the present example of FIG. 1 in that the magnetic field sources 8, 81, 82 are provided in the interior of the cylindrical vaporization cathode 2, 21, 22 and are stationary in the peripheral direction with respect to a rotation of the vaporization cathodes 2, 21, 22, which rotated about a longitudinal axis A in an operational state; however; the magnetic field sources 8, 81, 82 are movable in the longitudinal direction along the longitudinal axis A so that the magnetic field sources 8, 81, 82 can be removed from the cylindrical vaporization cathode 21 and/or from the cylindrical coating cathode as required.

In another embodiment it is also possible that the magnetic field sources 8, 81, 82 act as so called “virtual shutters” in a manner known per se, in that by rotating the magnetic field sources 8, 81, 82 in the peripheral direction about the cylinder axis A the magnetic field at the surface of the cylindrical vaporization source 2, 21, 22 is rotated essentially in a direction e.g. toward the chamber wall so that vaporized target material 200, 201, 202 no longer reaches the surface of the substrate.

It is understood that in another embodiment the strength of the magnetic field source at the vaporization cathode 2, 21, 22 can also be influenced in that instead of permanent magnets 8, 81, 82 electromagnets 8, 81, 82 are, for example, advantageously provided in the vaporization cathode 2, 21, 22 whose strength and orientation can be set by suitable adjustment of an electric current through the coils of the electromagnets 8, 81, 82.

Or the magnetic field source 8, 81, 82 can itself also be rotated about the longitudinal axis A of the vaporization cathode 2, 21, 22, as mentioned, so that, for example, by a suitable rotation of the magnetic field source 8, 81, 82 a surface acted on by the magnetic field in a first mode of operation is directed in a direction toward the substrate plate ST on which preferably a plurality of substrates S to be coated are arranged so that they can be coated in an ideal manner by the target material 200, 201, 202 vaporized from the vaporization cathode 2, 21, 22, with in a second mode of operation the magnetic field source 8, 81, 82 in the interior of the vaporization cathode 2, 21, 22 being rotated in such a way about the longitudinal axis A that the surface of the vaporization cathode 2, 21, 22 being acted on by the magnetic field is orientated, e.g. facing the chamber wall of the process chamber 3 so that the vaporized target material 200, 201, 202 is deposited essentially on the chamber wall of the process chamber 3 and that the substrate S is essentially no longer being coated by the corresponding vaporization source 2, 21, 22. It is understood that the previously described measures for the influencing and change of the magnetic field at the surface of the vaporization cathode 2, 21, 22 can also be suitably combined in an advantageous manner.

FIG. 2 shows a first embodiment of a vaporization cathode 2, 21, 22 in slightly more detail with a permanent magnetic field source 8, 81, 82. The vaporization cathode 2, 21, 22 of FIG. 2 which can, for example, be a vaporization cathode 21 or an arc cathode 22 bears on an outer cylinder surface 210, the target material 200, 201, 202 with which the substrate S is to be coated. Thus, for example, in one and the same process chamber 3 the vaporization cathode 21 can be equipped with a different target material 200, 201 than the arc cathode 22, which includes a different target material 200, 202 so that in particular complex combined layered systems can be produced. Naturally, the vaporization cathode 21 and the arc cathode 22 can also be equipped with the same target material 200, 201, 202.

In certain cases it is even possible that different regions of the sputtering cathode 21 and/or of the arc cathode 22 are provided with different target materials 200, 201, 202 so that through the suitable control and/or regulation of the arc different coatings and/or partial coatings can be applied.

Between the hollow interior I and the cylinder surface 210 a cooling gap K is provided, through which a coolant, for example cooling water, is circulated in the operating state which cools the vaporization cathode 2, 21, 22 in the operating state. The target material 200, 201, 202 is in this respect essential vaporized in the region B as the magnetic field generated by the magnetic field source 8, 81, 82 focuses the arc and the sputtering ions for the vaporization of the target material 200, 201, 202 onto the region B.

So that the target material 200, 201, 202 is uniformly eroded from the surface of the vaporization cathode 2, 21, 22, in the operating state the vaporization cathode 2, 21, 22 rotates about the longitudinal axis A while the magnetic field source does not rotate so that the region B migrates in accordance with this rotation in the peripheral direction over the surface of the vaporization cathode 2, 21, 22.

FIG. 3 shows a second embodiment of a vaporization cathode 2, 21, 22 with a permanent magnetic field source 8, 81, 82. The example of FIG. 3 differs from the one in FIG. 2 in that an additional magnetic field source 8, 81, 82 is provided. Target material 200, 201, 202 can thereby, for example, be simultaneously vaporized in the two corresponding regions on the vaporization cathode through a suitable spatial arrangement of the vaporization cathode 2, 21, 22 and/or through a suitable alignment of the magnetic field source 8, 81, 82. It is even possible that different target materials 200, 201, 202 are provided on one and the same vaporization cathode 2, 21, 22 in the two different surface regions which are associated with the magnetic field sources 8, 81, 82 so that different coatings can be vapor deposited onto the substrate S with one and the same vaporization cathode at the same time or following one another.

As previously mentioned the magnetic field source 8, 81, 82 can also be advantageously realized, for example, by electromagnets 8, 81, 82. Two special embodiments are respectively shown in FIG. 4, showing a central coil winding 800, and FIG. 5 showing two separate outer coil windings 800. It is understood that depending on the adaptation and arrangement of the coil winding 800 special magnetic field geometries can be produced depending on the demand.

The person of ordinary skill in the art knows how to choose corresponding arrangements for specific applications and moreover knows a whole further series of further magnetic field configurations which differ from the exemplary examples of FIG. 2 to FIG. 5.

It is understood that the embodiments previously explained and schematically shown in the Figures can also be advantageously combined with one another to further embodiments, to satisfy specific demands in practice.

1. A vaporization apparatus for the vaporization of a target material (200, 201, 202), including a process chamber (3) for the setting up and maintenance of a gas atmosphere and having an input (4) and an outlet (5) for a process gas, as well as a anode (6, 61) and a cylindrical vaporization cathode (2, 21, 22) formed as a target (2, 21, 22), the cylindrical vaporization cathode (2, 21, 22) including target material (200, 201, 202), wherein in addition an electrical source of energy (7, 71, 72) is provided for the generation of an electric potential between the anode (6, 61) and the cathode (2, 21, 22) so that the target material (200, 201, 202) of the cylindrical cathode (2, 21, 22) can be transferred into a vapor phase by means of the electrical source of energy (7, 71, 72) and wherein a magnetic field source (8, 81, 82) generating a magnetic field is provided, characterized in that a cylindrical sputtering cathode (2, 21) and a cylindrical arc cathode (2, 22) are simultaneously provided in the process chamber (3).

2. A vaporization apparatus in accordance with claim 1, wherein the cylindrical sputtering cathode (2, 21) and/or the cylindrical arc cathode (2, 22) is adapted for rotation about a longitudinal axis (A).

3. A vaporization apparatus in accordance with claim 1, wherein the magnetic field source (8, 81, 82) is provided in an interior (I) of the cylindrical sputtering cathode (2, 21), and/or in an interior (I) of the cylindrical arc cathode (2, 22) and/or the cylindrical sputtering cathode (2, 21) and/or the cylindrical arc cathode (2, 22) is rotatably arranged relative to the magnetic filed source (8, 81, 82).

4. A vaporization apparatus in accordance with claim 1, wherein the magnetic field source (8, 81, 82) is a permanent magnet (8, 81, 82) and/or an electromagnet (8, 81, 82).

5. A vaporization apparatus in accordance with claim 1, wherein a position of the magnetic field source (8, 81, 82) can be set in the interior (I) of the cylindrical sputtering cathode (2, 21) and/or in the interior (I) of the cylindrical arc cathode (2, 22), in particular in relation to an axial position and/or to a radial position and/or in relation to a peripheral direction.

6. A vaporization apparatus in accordance with claim 1, wherein a strength of the magnetic field of the magnetic field source (8, 81, 82) is settable and/or controllable, wherein the magnetic field source (8, 81, 82) is preferably provided and arranged in such a way that a magnetic field strength of the magnetic field is changeable in a presetable region of the cylindrical vaporization cathode (2, 21, 22).

7. A vaporization apparatus in accordance with claim, wherein a balanced magnetron (2, 21) and/or an imbalanced magnetron (2, 21) is provided as the sputtering cathode (2, 21).

8. A vaporization apparatus in accordance with claim 1, wherein one and the same vaporization cathode (2, 21, 22) is adapted and arranged in the process chamber such that the vaporization cathode (2, 21, 22) can be used as a sputtering cathode (2, 21) and also as an arc cathode (2, 22).

9. A method for the coating of a substrate (S) in a process chamber (3), in which a gas atmosphere is set up and maintained in the process chamber (3) and an anode (6, 61) and a cylindrical vaporization cathode (2, 21, 22) formed as a target (2, 21, 22) are provided in the process chamber (3), the cylindrical vaporization cathode (2, 21, 22) includes the target material (200, 201, 202) and the target material (200, 201, 202) of the cylindrical cathode (2, 21, 22) is transferred into a vapor phase by means of an electrical source of energy (7, 71, 72), wherein a magnetic field source (8, 81, 82) generating a magnetic field is provided in the process chamber (3) in such a way that, a magnetic field strength of the magnetic field can be changed in a preset region of the cylindrical vaporization cathode (2, 21, 22), characterized in that a cylindrical sputtering cathode (2, 21) and a cylindrical arc cathode (2, 22) are simultaneously provided in the process chamber (3) and in that the substrate (S) is coated with a arc vaporization process and/or with a cathode sputtering process.

10. A method in accordance with claim 9, wherein the cylindrical vaporization cathode (2, 21, 22) is rotated about a longitudinal axis (A) during a coating process for a uniform utilization of the target material (200, 201, 202).

11. A method in accordance with claim 9, wherein a position of the magnetic field source (8, 81, 82), is set in an interior (I) of the cylindrical sputtering cathode (2, 21) and/or in an interior (I) of the cylindrical arc cathode (2, 22), in particular in relation to an axial position and/or a radial position and/or in relation to a peripheral direction.

12. A method in accordance with claim 9, wherein a strength of the magnetic field of the magnetic field source (8, 81, 82) is set and/or controlled.

13. A method in accordance with claim 9, wherein one and the same vaporization cathode (2, 21, 22) is used as a sputtering cathode (2, 21) and as a arc cathode (2, 22).

14. A method in accordance with claim 9, wherein a balanced magnetron (2, 21) and/or an imbalanced magnetron (2, 21) is/are used as a sputtering cathode (2, 21).

15. A method in accordance with claim 9, wherein the coating process is a DC sputtering process and/or an RF sputtering process and/or a pulsed sputtering process and/or a high power sputtering process and/or a DC arc vaporization process and/or a pulsed arc vaporization process.
